(19) United States
(12) Patent Application Publication
(10) Pub. No.: US 2016/0380045 A1
(43) Pub. Date: Dec. 29, 2016

(54) CRYSTALLINE SEMICONDUCTOR GROWTH ON AMORPHOUS AND POLY-CRYSTALLINE SUBSTRATES

(71) Applicant: Tivra Corporation, Pleasant Hill, CA (US)

(72) Inventors: Francisco Machuca, Oakland, CA (US); Robert Weiss, San Francisco, CA (US)

(21) Appl. No.: 15/161,111

(22) Filed: May 20, 2016

Related U.S. Application Data
(60) Provisional application No. 62/233,157, filed on Sep. 25, 2015.
(60) Provisional application No. 62/184,692, filed on Jun. 25, 2015.

(51) Int. Cl. H01L 29/04; H01L 21/02; H01L 29/20

(52) U.S. Cl. CPC H01L 29/04; H01L 29/2003; H01L 21/02609; H01L 21/0254

(57) ABSTRACT

A multilayer semiconductor structure including at least in part a substrate and an III-N film layer. The substrate's constant of thermal expansion being substantially matched to the III-N film's constant of thermal expansion. The multilayer semiconductor structure may also include a crystal matching layer that has a lattice constant that substantially matches the lattice of constant of the III-N film. By not relying on the substrate for lattice matching the III-N film, the multilayer structure allows greater flexibility in the selection of an applicable substrate.

### CROSS REFERENCE RELATED APPLICATIONS

The present application claims benefit under 35 USC 119 (e) of U.S. Provisional Application No. 62/184,692 entitled “Power Devices and LED Architectures Enabled by Bulk Quality Seeded Growth of a Member in the Solid Solution of AlGaN-InGaN using Group III-Nitride Crystal Matching Layer (“CML”) film” filed Jun. 25, 2015; and of U.S. Provisional Application No. 62/233,157 entitled “Crystalline Semiconductor Growth on Amorphous and Poly-Crystalline Substrates” filed Sep. 25, 2015; the contents of which are incorporated herein by reference in their entirety.

The present application is related to U.S. patent application Ser. No. 14/106,657 entitled “Substrate Structures and Methods” filed Dec. 13, 2013; and to U.S. Pat. No. 8,956,952 entitled “Multilayer Substrate Structure and Method of Manufacturing the Same” filed Jun. 14, 2012, the contents of which are incorporated herein by reference in their entirety.

### TECHNICAL FIELD

The present invention is related to a multilayer semiconductor structure.

### BACKGROUND

Group III-Nitride (III-N) semiconductors such as AlN, AlGaN, GaN, and InGaN have become important materials for the production of Light Emitting Diodes (LEDs) and high power devices such as High-Electron-Mobility Transistors (HEMTs). Other III-Nitrides such as AlN and AlGaN are often included in device structures to mitigate mismatches in lattice and thermal expansion or as barrier or cladding layers in LEDs. Homoepitaxial growth of III-Nitrides has significant commercial limitations due to the absence of crystalline III-N substrates of reasonable cost and adequate size. Accordingly, heteroepitaxial growth methods have been developed wherein the III-Nitrides are grown on non-native substrates which are not well-matched to III-Nitride films in terms of crystal lattice dimensions or coefficient of thermal expansion (CTE). The mismatch between the substrate, also referred to as the growth template, and the III-N film results in undesirable defects in the films crystal structure and distortions such as bowing or cracking of the substrate/film stack. Current techniques for heteroepitaxy growth of III-N materials involve expensive processes while only partially mitigating defect generation resulting from lattice and CTE mismatch.

### BRIEF SUMMARY

Various embodiments of the invention seek to separate the CTE and lattice matching requirements for optimized III-Nitride growth by (1) creating a coefficient of thermal expansion match by providing a CTE-matched substrate and (2) creating a lattice-matched growth surface using a film or stack of films that create a crystalline lattice structure and/or lattice spacing.

Embodiments of the present invention may be achieved, for example, by selecting a bulk material for a substrate having a coefficient of thermal expansion substantially matching that of GaN or other semiconductor film and being manufactured as a wafer-like substrate with sub-nanometer-scale surface finish and selecting a thin film material or material stack that can be induced to have a crystal lattice substantially matching that of GaN. The thin film material or material stack is deposited on the bulk material in such a way that the thin film crystal structure is achieved independently of the bulk materials structure or lack of structure.

In one embodiment, the thin film crystalline layer or stack of layers establishes a crystal structure suitable for the nucleation and growth of III-Nitride films. Crystal quality can be further influence by adding seed layers, also known as underlayers, between the bulk substrate and the thin film stack. Seed layers can also be used to influence both crystal orientation and grain size of the thin film stack.

In one embodiment, the substrate is chosen to be CTE matched to the GaN film, but the substrate is not a single crystal or oriented multi-crystalline material and does not provide a crystalline template for the GaN growth. Instead, an oriented crystalline template for the GaN is provided by the intermediate layers (e.g. thin film crystalline layer, seed layer etc.).

In contrast with growth templates currently used in the art, embodiments of the invention do not rely on the structure of the bulk substrate to establish crystallinity. Crystallinity is established only in the thin film stack, with no required coincidence or crystal registry to the crystal lattice of the substrate. Consequently, the bulk material can be chosen based on CTE properties and suitability for mass production; opening the opportunity to use amorphous or low crystal quality poly-crystals with little to no crystalline orientation.

### BRIEF DESCRIPTION OF THE DRAWINGS

FIG. 1A is a cross sectional view of a multilayer semiconductor structure, in accordance with one exemplary embodiment of the present invention.

FIG. 1B is a cross sectional view of a multilayer semiconductor structure, in accordance with one exemplary embodiment of the present invention.

FIG. 1C is a cross sectional view of a multilayer semiconductor structure, in accordance with one exemplary embodiment of the present invention.

FIG. 1D is a cross sectional view of a multilayer semiconductor structure, in accordance with one exemplary embodiment of the present invention.

FIG. 1E is a cross sectional view of a multilayer semiconductor structure, in accordance with one exemplary embodiment of the present invention.

### DETAILED DESCRIPTION

The various embodiments are described more fully with reference to the accompanying drawings. These example embodiments are provided so that this disclosure will be thorough and complete, and will fully convey the scope of the invention to readers of this specification having knowledge in the technical field. Like numbers refer to like elements throughout.

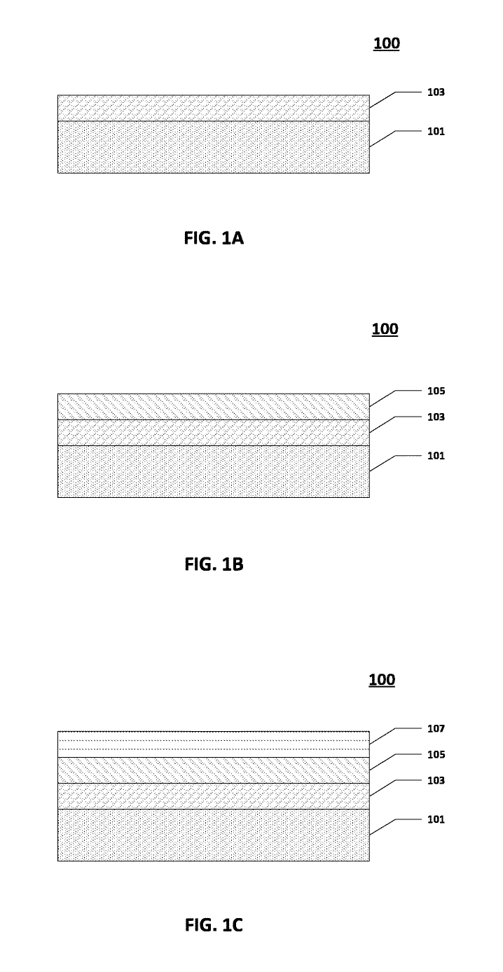

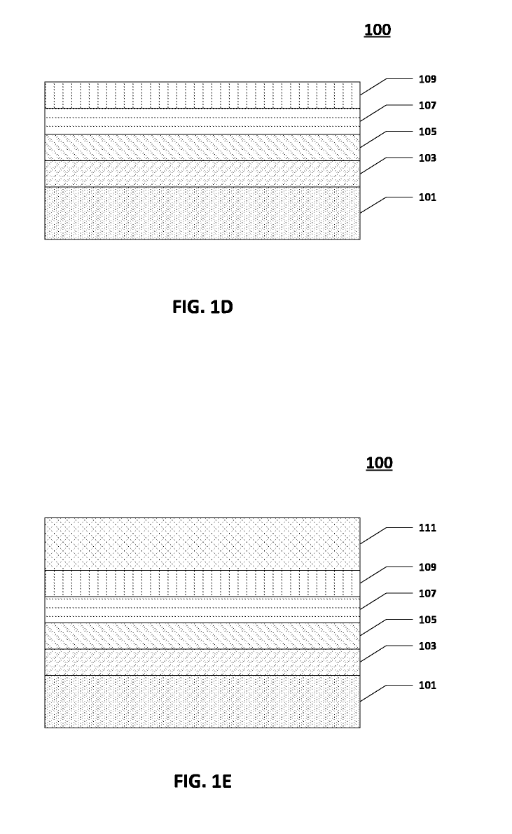

FIG. 1E illustrates a cross-section view of multilayer structure 100. Multilayer structure 100 includes several layers including: substrate 101, isolation layer 103, seed layer 105, crystal matching layer 107, nucleation layer 109, and III-N film 111. III-N film is a layer of semiconductor material consisting of at least one group III nitride material and/or their alloys (e.g. GaN, InN, AlGaN). In some embodiments one or more layers 103, 105, 109, and 111 may be optional. Although, embodiments of the present invention are described below with reference to an III-N film, it is understood that any semiconductor film may be used by adjusting crystal matching layer 107 to accommodate the lattice parameter of the chosen semiconductor film.

The process of forming multilayer structure 100 is described with relation to FIGS. 1A-1E. Now with reference to FIG. 1A, multilayer structure 100 includes, in part isolation layer 103 deposited via physical layer deposition (PVD) or chemical vapor deposition (CVD) on substrate 101. Depending on various applications, substrate 101 includes, in part a semiconductor material, a compound semiconductor material, or other type of material such as a metal or non-metal. For example, the materials comprising substrate 101 may include: molybdenum, molybdenum-copper, poly-aluminum nitride ceramic, mullite ceramic, sapphire, graphite, aluminum-oxynitrides, silicon, silicon carbide, zinc oxides and rare earth oxides, and/or other suitable materials. In some embodiments, substrate 101 has a thickness in the range of 250 microns—1 mm. Depending on various applications and material composition, substrate 101 may take different structural forms. For example, substrate 101 may include an amorphous or poly-crystalline structure. However, in other embodiments, substrate 101 may include a single crystal (e.g. sapphire and silicon) or oriented multi-crystalline material. Regardless of the material or the structure, substrate 101 has a coefficient of thermal expansion (CTE) substantially matching the CTE of III-N film 111.

In accordance with one embodiment of the present invention, substrate 101 for the multilayer structure 100 may be chosen for its CTE properties, and there may be no reliance on the underlying crystal structure of the substrate. As a result, substrate 101 may include any material so long as substrate 101 has a CTE (ppm per degree Kelvin or 10̂−6/K) that substantially matches the III-N film 111. Instead of depending on substrate 101 for providing a crystal structure or template for III-N film 111 growth, the crystal matching layer 107 may completely replace, upgrade, or enhance the crystal structure of substrate 101 and directly enable III-N film 111 growth.

What is considered a substantially matched CTE depends on the application of the multilayer structure 100. In accordance with one embodiment, the substrate's CTE is within ±5% of the III-N film's CTE to be substantially matching. For example, in order for a substrate to be substantially matched with GaN (having an approximate CTE of 5.6), the substrate has a CTE between 5.32 and 5.88. The CTE of molybdenum is approximately 5.4, and according to one embodiment, is substantially matched to the CTE of GaN. Applications in power semiconductor discrete devices, GaN based integrated circuits (IC), or high current density optoelectronic devices; of which creating significant thermal stresses during fabrication of semiconductor device layer on the substrate would benefit from a substantial match in CTE in accordance with one embodiment. On the other hand, a silicon substrate with an approximate CTE of 2.6, would not be substantially matched to the CTE of the GaN film according to one embodiment. According to one embodiment, other materials that substantially match GaN include but are not limited to: Zirconium, Molybdenum, pure Arsenic, ZrTi (86:14 atomic percent), Carbide, and multigrained or polycrystalline Aluminum Nitride ceramic (1 to 1 atomic ratio).

In one embodiment, a substrate's CTE substantially matches the III-N film's CTE if the substrate's CTE is within 1 unit (where 1 unit is a ppm per degree Kelvin) of the III-N film's CTE. In accordance with this embodiment, materials that substantially match GaN include, but are not limited to: Zirconium, Osmium, Hafnium, Chromium, Molybdenum, Cerium, Rhenium, Tantalum, Iridium, Ruthenium, Tungsten, Praseodymium, Germanium, InAs, InP, InSb, AlAs, AlP, GaP, GaAs, pure Arsenic, Molybdenum-Copper, alloys of ZrTi, alloys of HfTi, Carbide, and poly-Aluminum Nitride ceramic (1 to 1 atomic ratio), Titanium, alloys of Molybdenum, alloys of Tungsten, alloys of Nickel, alloys of Niobium, alloys of Iridium, Kovar, alloys of Neodymium, Molybdenum-Copper, metal alloys of Ti, alloys of Zr, alloys of Hf, Carbide, poly-Aluminum Nitride ceramic of varying atomic proportions, alumina ceramic, titania, polycrystalline SiC. Typical applications requiring a substantially matched CTE according to this embodiment include, but are not limited to, thermal annealing, thermal degas or cleaning steps, physical or chemical film growth, recrystallization steps, metal contact firing steps, implantation and subsequent annealing, or any circuit fabrication steps (mask/lithography, growth, etch/pattern, metallization, CMP, etc) that may require temperature heat up/cool down steps in any portion of the range of 1400 Celsius to room temperature and must remain below 50 microns of substrate or wafer bow over any wafer diameter.

In another embodiment, a substrate's CTE substantially matches the III-N film's CTE if the substrate's CTE is within 0.5 unit (where the unit is a ppm per degree Kelvin) of the III-N film's CTE. For example, molybdenum has a CTE of approximately 5.4, which is within 0.5 of the CTE (unit of ppm per degree Kelvin) of GaN. In accordance with this embodiment, other materials that substantially match GaN include, but are not limited to: Molybdenum, pure Arsenic, Chromium, ZrTi (86:14), Carbide, Germanium, Osmium, Zirconium, Hafnium, InSb, Kovar, and poly-Aluminum Nitride ceramic (1 to 1 atomic ratio). Typical applications requiring a substantially matched CTE according to this embodiment include, but are not limited to: thermal annealing, thermal degas or cleaning steps, physical or chemical film growth, recrystallization steps, metal contact firing steps, implantation and subsequent annealing, or any circuit fabrication step (mask/lithography, growth, etch/pattern, metallization, CMP, etc.) that requires temperature heat up/cool down steps in any portion of the range of 1400 Celsius to room temperature, and must remain below 25 microns of substrate or wafer bow over any wafer diameter.

It is known that differences in CTE between a film and substrate can lead to residual stress between the film and the substrate as a result of heating and cooling processes during film deposition. Residual stress may result in compression or tension on the film. When the film compresses, the residual stress may be relieved by buckling of the film, but when the film is under tension, the residual stress may be relieved by cracking of the film. In one embodiment, in the case of a CTE mismatch between the film and the substrate that results in residual stress, the multilayer structure 100 should be designed to create compression on III-N film 111 rather than tension on III-N film 111. Moreover, maintaining wafer flatness is crucial to manufacture devices from the deposited GaN film(s) on the substrates. For any film thickness of GaN grown on a substrate where the film thickness is less than the substrate thickness, Table 1 enumerates designs that would be allowed assuming increasing substrate diameter and corresponding thickness to achieve two categories of tolerable bow or warp, namely less than 25 microns and lower than 50 microns (limits mainly set by automatic handling equipment and limits in depth of focus for lithographic steps).

TABLE 1

| | | | | Extrinsic | | |
|---|---|---|---|---|---|---|
| | | | | Strain | | |
| | | | Delta CTE | allowed @ | | |
| Assumed | | CTE | allowed by | 1400 C. | Calculated | |
| Thickness | Diameter | Match | matching | cool down | max Bow | Curvature |
| (um) | (mm) | Range | (ppm/C.) | cycle | (um) | (1/km) |
| 675 | 150 | +/−5% | 0.28 | −0.000385 | 3.21 | 1.14 |
| 725 | 200 | +/−5% | 0.28 | −0.000385 | 5.31 | 1.06 |
| 825 | 300 | +/−5% | 0.28 | −0.000385 | 10.50 | 0.93 |
| 675 | 150 | +/−0.5 | 0.5 | −0.0006875 | 5.73 | 2.04 |
| 725 | 200 | +/−0.5 | 0.5 | −0.0006875 | 9.48 | 1.90 |
| 825 | 300 | +/−0.5 | 0.5 | −0.0006875 | 18.75 | 1.67 |
| 675 | 150 | +/−1.0 | 1.0 | −0.001375 | 11.46 | 4.07 |
| 725 | 200 | +/−1.0 | 1.0 | −0.001375 | 18.97 | 3.79 |
| 825 | 300 | +/−1.0 | 1.0 | −0.001375 | 37.50 | 3.33 |

To remain below 50 microns of bow or warp any wafer diameter and any of the 3 ranges of CTE matching can be used (+/−5% of value, +/−0.5, and +/−1.0 about the value of GaN). Similarly to remain below 25 microns of bow or warp all wafer diameters are allowed for all 3 ranges of CTE matching with the exception of 300 mm for +/−1.0 ppm about the GaN value. This latter condition could be reached if wafer thickness is allowed to increase by industry standards to 1200 mm (<25 microns bow for a +/−1 ppm delta in CTE compared to GaN on 300 mm diameter).

As previously stated, the isolation layer 103 is deposited on substrate 101 by any suitable PVD or CVD process (e.g. Plasma-enhanced chemical vapor disposition (PECVD), Low-pressure chemical vapor deposition (LPCVD), Atomic layer deposition (ALD), Plasma Torch, Liquid phase epitaxy (LPE), and spin coat annealing) In some embodiments, the thickness of the isolation layer 103 is in the range of 1 nm to 500 nm. In one embodiment, the isolation layer 103 is deposited via a sputtering technique. The isolation layer 103 may serve as a smooth and non-reacting surface for subsequent layers. The isolation layer 103 may be also used to prevent subsequent layers from replicating an undesirable crystal structure that may be found in substrate 101. Materials that could be used in the isolation layer 103 would have one or more of the following function(s) and properties: amorphous or lack of crystal structure, be deposited as conformal films, low stress, and the capability to fill in high aspect ratio morphology such as pits, grooves, or ledges. For example, glasses, glassy carbon, metal nitrides, oxy-nitrides, and oxides such as SiO2 are examples of materials that can be included in the isolation layer 103. In some embodiments, where the substrate has a desirable crystal structure isolation layer 103 may be omitted from structure 100. In one embodiment, isolation layer 103 includes silicon dioxide or silicon nitride. In some embodiments, isolation layer 103 includes multiple layers.

Now with reference to FIG. 1B, seed layer 105 is deposited on isolation layer 103. Seed layer 105 includes, in part one or more thin film layers deposited on top of each other (i.e. in a stack) by any known CVD or PVD process. In some embodiments, the thickness of the seed layer 105 is in the range of 1 atomic layer to 500 nm. Seed layer 105 defines crystal orientation, crystal polarity, crystal structure type, and/or grain size for crystal matching layer 107 and may consist of multiple layers. The seed layer 105 includes, in part at least one or more of the following materials: iron, chromium, titanium, cobalt, ruthenium, tantalum, nickel, and molybdenum. In one embodiment, seed layers will be grown using PVD techniques and will be grown at appropriate temperatures and target power to achieve dense films. In the case of wurtzite structure films, the c-axis will be normal to the growth plane, and in the case of cubic crystals, the 111 axis will be normal to the growth plane. For example, a first layer in seed layer 105 includes titanium (Ti) and may be used to lower the surface energy of substrate 101 in order to improve the growth of subsequent layers by thermodynamically favoring the (0001) direction to be normal to the plane. In another example, substrate 101 is an aluminum nitride ceramic wafer and seed layer 105 is a thin film layer of cobalt, which together establish a hexagonal close packed (HCP) structure with the c-axis perpendicular to substrate 101. The HCP structure created by seed layer 105 influences the crystal orientation of the subsequent crystal matching layer 107. In other embodiments, seed layer 105 may be used to form a face center cubic (FCC) structure, HCP, or a body centered cubic (BCC) structure, which allows the crystal matching layer 107 to grow with the HCP crystal structure. Stated another way, the seed layer 105 does not have to be a matched crystal structure to the crystal matching layer 107; instead the seed layer 105 is an appropriate crystal structure. In some embodiments where substrate 101 presents a suitable crystal structure, both isolation layer 103 and seed layer 105 may be omitted from multilayer structure 100. Examples of such substrates could include ZrTi, Molybdebdum, HfTi, c-oriented polycrystalline Aluminum Nitride, and c-oriented poly-crystalline SiC, materials with CTE within +/−5% about the value of GaN.

With reference to FIG. 1C, crystal matching layer 107 is deposited on seed layer 105. The crystal matching layer may be deposited on seed layer 105 using any known and suitable PVD or CVD method. Because, substrate 101 is selected due to its CTE qualities in relation to III-N film 111, there may exist lattice constant mismatch between substrate 101 and III-N film 111. In particular, the lattice mismatch can be extremely different, and may be greater than the 1-3% typically sought for heteroepitaxy. Embodiments of the invention allow for independently matching the CTE of substrate 101 and III-N film 111 without regard to the lattice parameter of substrate 101 of multilayer structure 100. The crystal matching layer 107 includes, in part one or more metal layers that accommodate and/or eliminate the lattice constant mismatch between substrate 101 and III-N film 111. The thickness of crystal matching layer 107 ranges between 5 nm and 1000 nm.

The crystal matching layer includes, in part two or more constituent elements, for example two constituents includes, in part a first chemical element and a second chemical element to form a constituent element alloy. The constituent elements may have similar crystal structures at room temperature, such as an HCP structure. In addition to crystal structures, the constituent elements may have similar chemical properties. In one embodiment, the first and second chemical elements may both belong to group four elements (e.g. titanium (Ti), zirconium (Zr), hafnium (Hf) and rutherfordium (Rf)), alloys of the group four elements, nitrides of the group four elements, and the alloys further alloyed with the elements of tantalum (Ta), boron (B), silicon (Si), and the crystal matching layer 107 is capped with the nucleation layer 109. The constituent element alloy may include a third chemical element or more elements which have similar crystal structures and similar chemical properties. The different chemical elements and the proportions of those chemical elements that make up the constituent element alloy(s) of crystal matching layer 107 may be modified to substantially match the lattice constant of III-N film 111. According one embodiment, ranges for substantial match for heteroepitaxy to mimic homo-epitaxy and do not form crystal misfit and dislocation defects is within the range of +/−1-3% of the value of the III-N film layer's lattice constant (layer 111). The process of selecting and proportioning these chemical elements is further described in U.S. patent application Ser. No. 8,956,952 and U.S. patent application Ser. No. 14/106,657.

By utilizing crystal matching layer 107, potential residual stress, along with point and extended defects such as crystal misfit and threading dislocation, may all together be lowered or completely removed which might otherwise occur in III-N film 111 as a result of the difference in the lattice constants between substrate 101 and III-N film 111. Substantially matching the lattice constants (i.e. +/−1-3%) of crystal matching layer 107 and III-N film 111 aids in the growth of the highest crystalline quality III-N film.

Now with reference to FIG. 1D, nucleation layer 109 is deposited on the crystal matching layer 107. The nucleation layer 109 may be deposited by any suitable PVD or CVD process. The nucleation layer provides a surface that is chemically and physically compatible with III-N film 111. Nucleation layer 109 also provides a suitable growth environment (i.e. chemistry, crystal polarity, and symmetry) for growing III-N film 111. In some embodiments, nucleation layer 109 includes, in part a nitride film (e.g. aluminum nitride (AlN)). In one embodiment, nucleation layer 109 is deposited in the range of 1 nm to 200 nm and is pseudomorphically grown to maintain the lattice of the crystal matching layer 107. The nucleation layer 109 may be pseudomorphically (with the same lattice parameter of crystal matching layer 107) grown aluminum nitride (AlN), aluminum gallium nitride (AlGaN), gallium nitride (GaN), indium gallium nitride (InGaN). In one embodiment, the nucleation layer 109 has the same lattice parameter as the crystal matching layer 107.

With reference to FIG. 1E, III-N film 111 is deposited on the nucleation layer 109. The III-N film may be epitaxial grown by any suitable PVD or CVD process. In one embodiment, the III-N film 111 is a semiconductor compound and a member of the solid solution gallium nitride (GaN) and its alloys with aluminum (Al), indium (In), boron (B), including and not limited to: aluminum nitride (AlN), aluminum gallium nitride (AlGaN), gallium nitride (GaN), indium nitride (InN), indium gallium nitride (InGaN), and boron nitride (BN). A novel concept presented by the embodiments of the present invention is that by removing lattice mismatch and CTE mismatch independently using multilayer structure 100, for the first time there is no upper limit to the thickness of the III-N film 111 that can be grown.

In one embodiment, multilayer structure 100 includes the following layers: poly ALN substrate with a diameter of 200 mm and a thickness of 825 um (101), SiO2 with a thickness of 10 nm (103), Si3N4 with a thickness of 200 nm (103), tantalum seed layer with a thickness of 10 nm (105), ZrTi with a thickness of 1000 nm (107), AlN with a thickness of 200 nm (109), and device layers of GaN with a thickness of 1 um to 50 um (111).

Many modifications and other example embodiments set forth herein will bring to mind to the reader knowledgeable in the technical field to which these example pertain to having the benefit of the teachings presented in the foregoing descriptions and the associated drawings. Therefore, it is to be understood that the embodiments are not to be limited to the specific ones disclosed and that modifications and other embodiments are intended to be included within the scope of the claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions other than those explicitly described above are also contemplated as may be set forth in some of the appended claims.

What is claimed is:

1. A multilayer structure comprising:
a semiconductor substrate;
a first layer deposited on the substrate and comprising one or more materials forming a crystal structure;
and a third layer formed above the first layer, wherein the substrate has a coefficient of thermal expansion (CTE) substantially matching a CTE of the third layer, and wherein the first layer has a lattice constant substantially matching a lattice constant of the third layer.

2. The multilayer structure of claim 1, further comprising: a second layer formed between the substrate and the first layer, wherein the second layer defines crystal orientation and grain size of the first layer.

3. The multilayer structure of claim 2, wherein the second layer comprises at least one or more of: iron, chromium, titanium, cobalt, ruthenium, tantalum, nickel, and molybdenum.

4. The multilayer structure of claim 1, wherein the substrate is not a single crystal substrate.

5. The multilayer structure of claim 1, wherein the substrate is an oriented multi-crystalline material.

6. The multilayer structure of claim 1, wherein the first layer includes one or more of the following materials: ZrX, HfX, TiX, ZrXN, RfX,HfXN, TiXN, where X is one or more of the following elements: Ta, Si, Ti, Zr, Hf, or B.

7. The multilayer structure of claim 1, further comprising a third layer deposited on the first layer, wherein the third layer includes one or more of the following materials: AlN, AlGaN, GaN, InGaN.

8. A method for manufacturing a multilayer structure comprising:
forming a first layer over a semiconductor substrate, said first layer comprising one or more materials forming a crystal structure; and
forming a third layer above the first layer, wherein the substrate has a coefficient of thermal expansion (CTE) substantially matching a CTE of the third layer, and wherein the first layer has a lattice constant substantially matching a lattice constant of the third layer.

9. The method of claim 8, further comprising depositing a second layer between the substrate and the first layer, wherein the second layer defines crystal orientation and grain size of the first layer.

10. The method of claim 9, wherein the second layer comprises at least one or more of: iron, chromium, titanium, cobalt, ruthenium, tantalum, nickel, and molybdenum.

11. The method of claim 8, wherein the substrate is not a single crystal substrate.

12. The method of claim 8, wherein the substrate is an oriented multi-crystalline material.

13. The method of claim 8, wherein the first layer includes one or more of the following materials: ZrX, HfX, TiX, ZrXN, RfX,HfXN, TiXN, where X is one or more of the following elements: Ta, Si, Ti, Zr, Hf, or B.

14. The method of claim 8, further comprising: depositing a third layer on the first layer, wherein the third layer includes one or more of the following materials: AlN, AlGaN, GaN, InGaN.

15. The multilayer structure of claim 1, wherein the semiconductor substrate has either amorphous or a poly-crystalline structure.

16. The method of claim 8, wherein the semiconductor substrate has either amorphous or a poly-crystalline structure.
